(19) United States
(12) Patent Application Publication
(10) Pub. No.: US 2026/0337763 A1
(43) Pub. Date: Oct. 29, 2026

(54) METHOD OF FORMING A STRUCTURE INCLUDING A SILICON CARBON NITRIDE LAYER

(71) Applicant: ASM IP Holding B.V., Almere (NL)

(72) Inventor: Takuya Kurotori, Kawasaki-shi (JP)

(21) Appl. No.: 19/650,718

(22) Filed: Apr. 17, 2026

Related U.S. Application Data
(60) Provisional application No. 63/792,862, filed on Apr. 22, 2025.

(51) Int. Cl. C23C 16/36; C23C 16/505

(52) U.S. Cl. CPC C23C 16/36; C23C 16/505

(57) ABSTRACT

A method of forming a structure comprising a silicon carbon nitride layer is disclosed. An exemplary method includes using high frequency power during deposition of the silicon carbon nitride layer to form films with desired properties. In some cases, a continuous plasma is used to form a silicon carbon nitride layer and a silicon carbon oxynitride layer.

### CROSS-REFERENCE TO RELATED APPLICATIONS

This application claims priority to U.S. Provisional Patent Application Ser. No. 63/792,862 filed Apr. 22, 2025 titled METHOD OF FORMING A STRUCTURE INCLUDING A SILICON CARBON NITRIDE LAYER, the disclosure of which is hereby incorporated by reference in its entirety.

### FIELD OF INVENTION

The present disclosure generally relates to methods of forming thin films and to structures including the thin films. More particularly, the disclosure relates to methods of forming structures that include a layer comprising silicon, carbon, and nitrogen, and to structures including such layers.

### BACKGROUND OF THE DISCLOSURE

Silicon nitride material, such as material containing silicon carbon nitride (SiCN), can be used for a wide variety of applications. For example, during the formation of electronic devices, such material can be used to form insulating layers, etch stop layers, and/or spacers.

For several applications, it may be desirable for the silicon nitride material to be relatively resistant to wet etching processes, such as wet etching using hydrofluoric acid and/or hot phosphoric acid, and/or to ashing processes. In addition, it may be desirable that such material exhibits a relatively low dielectric constant. While SiCN can exhibit desired dielectric constants, such material may not exhibit desired etch stop properties.

Silicon nitride material, such as silicon oxycarbonitride (SiOCN), can exhibit desired etch rate or etch stop and/or ashing resistance. However, SiOCN may not exhibit desired dielectric constants. Furthermore, deposition of SiOCN on a surface of a substrate may cause undesired oxidation of the substrate surface.

For many applications, it may be desirable to deposit SiCN and/or SiOCN on a surface of a substrate at relatively low (e.g., less than 650° C.) temperatures. Plasma-enhanced chemical vapor deposition (PECVD) can be used to deposit SiCN and/or SiOCN layers on a substrate surface at relatively low temperatures.

Typical PECVD techniques to deposit SiCN and/or SiOCN layers include use of a silicon precursor and a reactant. The reactant is typically used to form a plasma. Activated species from the plasma react with the silicon precursor to form the SiCN and/or SiOCN. Although such techniques may work well for some applications, properties of the SiCN and/or SiOCN layers using activated species formed using typical plasma formation techniques may not allow for a combination of desired etch selectivity, dielectric constant, density, and/or other properties. Additionally or alternatively, such techniques may be relatively time consuming. Accordingly, improved methods are desired for forming structures that include SiCN and/or SiOCN.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

Various embodiments of the present disclosure relate to methods of forming a structure comprising a silicon carbon nitride layer. While the ways in which various embodiments of the present disclosure address drawbacks of prior methods and structures are discussed in more detail below, in general, various embodiments of the disclosure provide improved methods to form SiCN and/or SiOCN (also referred to herein as SiCON) layers with desired properties, such as desired etch resistance, desired dielectric constant, desired composition, desired density, and/or the like. Additionally or alternatively, exemplary methods provide a relatively efficient process to form a structure that includes both SiCN and SiOCN layers.

In accordance with at least one embodiment of the disclosure, a method of forming a structure comprising a silicon carbon nitride layer includes providing a substrate within a reaction chamber, providing a silicon precursor within the reaction chamber, providing a nitrogen-containing reactant within the reaction chamber, and forming a plasma within the reaction chamber while providing one or more of the silicon precursor and the nitrogen-containing reactant. The forming the plasma can include providing a plasma power to an electrode within the reaction chamber. In accordance with examples of the disclosure, a frequency of the plasma power is equal to or greater than 60 MHz. Plasma power frequency equal to or greater than 60 MHz allows for formation of silicon carbon nitride layers with desired properties (e.g., a density of greater than 2.3 g/cm³ and a dielectric constant of less than 5 or 4.5). In accordance with various examples of these embodiments, the silicon precursor comprises one or more of an aminosilane or an alkylsilane. In accordance with further examples, the nitrogen-containing reactant comprises one or more of nitrogen, ammonia (NH₃), hydrazine (N₂H₄), triazane (N₃H₅), an alkyl substituted hydrazine, triazine, or a C1-C4 amine. The method can further include a step of forming a silicon carbon oxynitride layer on the silicon carbon nitride layer.

In accordance with additional embodiments of the disclosure, a continuous method for forming a structure comprising a silicon carbon nitride layer and a silicon carbon oxynitride layer is provided. The continuous method can be used to form the silicon carbon nitride layer and the silicon carbon oxynitride layer in an efficient and time-saving manner. In accordance with various examples, the continuous method includes providing a substrate within a reaction chamber, providing a silicon precursor within the reaction chamber, providing a first nitrogen-containing reactant within the reaction chamber, providing a second nitrogen-containing reactant within the reaction chamber, and forming a plasma by providing plasma power within the reaction chamber while providing one or more of the silicon precursor and the first nitrogen-containing reactant to form the layer of silicon carbon nitride. Exemplary methods further include, while maintaining the plasma, decreasing a flow of the second nitrogen-containing reactant and providing or increasing a flowrate of an oxygen-containing reactant during a transition period, and while continuing to maintain the plasma, forming the silicon carbon oxynitride layer. In accordance with various examples of these embodiments, a frequency of the plasma power is equal to or greater than 60 MHz. In some cases, the step of forming the plasma comprises providing a dual frequency plasma power, wherein at least one frequency of the dual frequency plasma power is equal to or greater than 60 MHz. In accordance with further examples, a flowrate of the second nitrogen-containing reactant decreases by about 40 percent or more during the transition period. In accordance with further examples, the oxygen-containing reactant includes carbon. In some cases, the oxygen-containing reactant comprises a mixture comprising a hydrogen-containing gas.

In accordance with further exemplary embodiments of the disclosure, a structure includes a layer comprising SiCN and/or SiOCN. The structures can be formed using, for example, a method as described herein.

In accordance with additional embodiments, a reactor system is provided. Exemplary reactor systems include a reaction chamber, a precursor source coupled to the reaction chamber, one or more reactant sources, and a controller. The controller can be configured to perform a method as described herein. The reactor system can include a plurality of reaction chambers. One or more steps that are performed by the controller can be performed in one or more of the plurality of reaction chambers.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method of forming a structure comprising a silicon carbon nitride layer in accordance with at least one embodiment of the disclosure.

FIG. 2 illustrates another method of forming a structure comprising a silicon carbon nitride layer in accordance with at least one embodiment of the disclosure.

FIG. 3 illustrates a timing sequence in accordance with at least one embodiment of the disclosure.

FIG. 4 illustrates a structure in accordance with at least one embodiment of the disclosure.

FIG. 5 illustrates a schematic diagram of a reactor system in accordance with examples of the disclosure.

FIG. 6 illustrates a schematic diagram of a reactor system, having multiple reaction chambers, in accordance with examples of the disclosure.

FIG. 7 illustrates dielectric constants versus film density, leakage, and stress for silicon carbon nitride layers in accordance with examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particularly disclosed embodiments described below.

The present disclosure generally relates to methods of forming a structure comprising a silicon carbon nitride layer. As set forth in more detail below, methods described herein can be used to form silicon carbon nitride layers with desired properties, such as relatively high density, relatively high wet etch resistance, relatively low dielectric constant, relatively low leakage current for an applied field, and/or with desired compositions, such as desired carbon concentrations.

Exemplary methods described herein can be used to form structures that can be used in a variety of applications, such as the formation of electronic devices. For example, the methods can be used to form structures suitable for cell isolation in 3D cross point memory devices, self-aligned vias, dummy gates, reverse tone patterns, PC RAM isolation, cut hard masks, DRAM storage node contact (SNC) isolation, or the like.

As used herein, the term substrate can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. Further, the substrate can include various features, such as gaps (e.g., recesses or vias), lines or protrusions, such as lines having gaps formed therebetween, and the like formed on or within at least a portion of a layer or bulk material of the substrate.

In some embodiments, film refers to a layer extending in a direction perpendicular to a thickness direction. In some embodiments, layer refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers.

In this disclosure, continuously or continuous or continually can refer to without breaking a vacuum, without interruption as a timeline, without any material intervening step, without changing treatment conditions, immediately thereafter, as a next step, or without an intervening discrete physical or chemical structure between two structures other than the two structures in some embodiments and depending on the context.

As used herein, a silicon carbon nitride layer or a layer comprising SiCN includes material with silicon, carbon, and nitrogen. In some embodiments, SiCN layers may comprise one or more elements in addition to Si, C, and N, such as H and/or O. In some embodiments, the SiCN layers may comprise from about or greater than 1.5% to about 50% carbon on an atomic basis. In some embodiments, the SiCN layers may comprise from about 3.0% to about 40% carbon on an atomic basis. In some embodiments, the SiCN layers may comprise from about 0% to about 6.0% oxygen on an atomic basis. In some embodiments, the SiCN layers may include substantially no oxygen on an atomic basis. In some embodiments, the SiCN layers may comprise from about 25% to about 50% silicon on an atomic basis. In some embodiments, the SiCN layers may comprise from about 30% to about 50% silicon on an atomic basis. In some embodiments, the SiCN layers may comprise from about 1.5% to about 40% hydrogen on an atomic basis. In some other embodiments, the SiCN layers may comprise from about or greater than 0% to about 50% on an atomic basis (at %).

As used herein, unless stated otherwise, a silicon carbon oxynitride (SiOCN) layer is not intended to limit, restrict, or define the bonding or chemical state, for example, the oxidation state, of any of Si, O, C, N and/or any other element in the film. Further, in some embodiments, SiOCN layers may comprise one or more elements in addition to Si, O, C, and N, such as H. In some embodiments, the SiOCN layers may comprise Si—C bonds and/or Si—O bonds. In some embodiments, the SiOCN layers may comprise more Si—O bonds than Si—C bonds, for example, a ratio of Si—O bonds to Si—C bonds may be from about 1:1 to about 10:1. In some embodiments, the SiOCN layers may comprise from about or greater than 0% to about 40% carbon on an atomic basis. In some embodiments, the SiOCN layers may comprise from about 0.1% to about 40% carbon on an atomic basis. In some embodiments, the SiOCN layers may comprise from about or greater than 0% to about 70% oxygen on an atomic basis. In some embodiments, the SiOCN layers may comprise from about 10% to about 70% oxygen on an atomic basis. In some embodiments, the SiOCN layers may comprise from about or greater than 20% to about 55% silicon on an atomic basis. In some embodiments, the SiOCN layers may comprise from about 10% to about 50% silicon on an atomic basis. In some embodiments, the SiOCN layers may comprise from about 3.0% to about 40%-hydrogen on an atomic basis. In some other embodiments, the SiOCN layers may comprise from about or greater than 0% to about 20% nitrogen on an atomic basis (at %).

A dielectric constant of the SiCN layer can range from about 3 to about 5.5 or about 3.6 to less than 5 or less than 4.5. Additionally or alternatively, a density of the SiCN layer can be greater than 2.3 g/cm³. Additional properties of SiCN and SiOCN layers in accordance with the disclosure are provided below.

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, or the like in some embodiments. Further, in this disclosure, the terms including, constituted by and having can refer independently to typically or broadly comprising, comprising, consisting essentially of, or consisting of in some embodiments. In this disclosure, any defined meanings do not necessarily exclude ordinary and customary meanings in some embodiments.

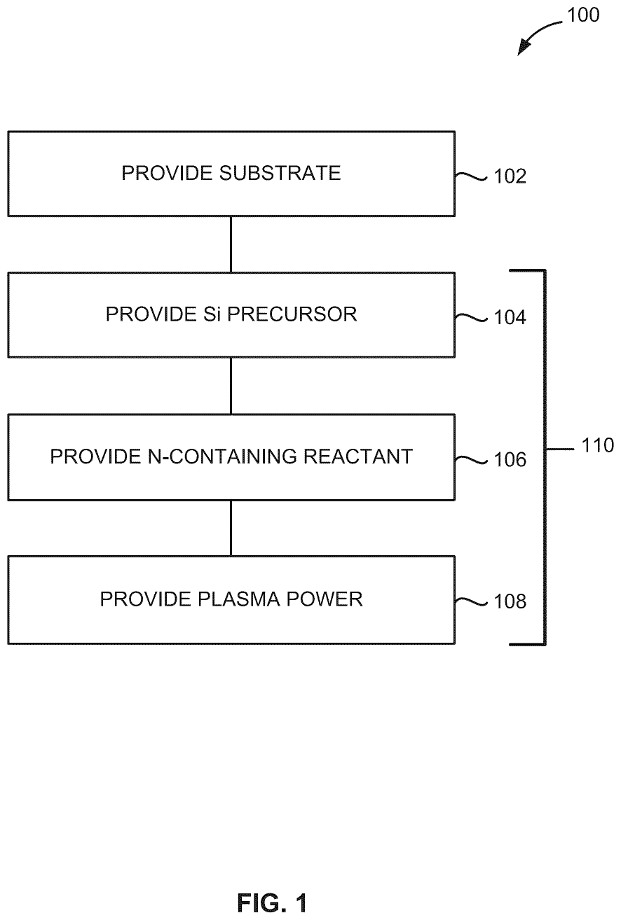

Turning now to the figures, FIG. 1 illustrates a method 100 in accordance with examples of the disclosure. Method 100 includes providing a substrate within a reaction chamber (step 102), providing a silicon precursor within the reaction chamber (step 104), providing a nitrogen-containing reactant within the reaction chamber (step 106), and forming a plasma within the reaction chamber while providing one or more of the silicon precursor and the nitrogen-containing reactant (step 108). Although separately illustrated, one or more (e.g., all) of steps 104-108 can overlap in time. For example, steps 104-108 can overlap in time to perform a plasma-enhanced chemical vapor deposition (PECVD) process, illustrated as 110.

The substrate provided during step 102 can be provided within any suitable reaction chamber of any suitable reactor. In accordance with examples of the disclosure, the reaction chamber can form part of a chemical vapor deposition (CVD) reactor, such as a PECVD reactor. The reactor can be a single substrate reactor or a batch reactor. A reactor including the reaction chamber can be provided with a heater to activate the reactions by elevating the temperature of one or more of the substrate and/or the reactants and/or precursors. An exemplary reactor and reactor system suitable for use with method 100 is described in more detail below.

After step 102 and during or before steps 102-108, the substrate can be brought to a desired temperature and pressure for forming the silicon carbon nitride layer. By way of examples, a temperature (e.g., of a substrate or a substrate support) within a reaction chamber can be between about 75° C. and about 500° C. A pressure within the reaction chamber during one or more of steps 104-108 can be between about 250 Pa and about 900 Pa.

During step 104, the silicon precursor is provided within the reaction chamber. The silicon precursor can be or include, for example, an aminosilane or an alkylsilane.

In some embodiments, a silicon precursor can be represented by the following formula,

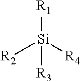

wherein at least one R₁-R₄ group is independently selected as an amine group or a C1-C4 alkyl group and where other R₁-R₄ groups can be independently selected from an amine group, a C1-C4 alkyl group, or H. Exemplary amine groups include C1-C4 alkyl amines.

In some cases, the silicon precursors can include two silicon atoms. In such cases, the silicon atoms can be bonded together or separately bonded to one or more other atoms.

By way of particular examples, the silicon precursor can be or include, for example, one or more of (SiH₃)₂NMe, (SiH₃)₂NEt, (SiH₃)₂N(iPr), (SiH₃)₂N(tBu), SiH₃NEt₂, SiH₃N(tBu)₂, SiH₂(NEt₂)₂, SiH₂(NMe₂)₂, SiH₂(NHSiMe₃)₂, SiH₂(NHtBu)₂, SiH₃N(iPr)₂, SiH(N(Me)₂)₃, SiH₂[N(Et)(Me)]₂, Si₂(NHEt)₆, Si(NHEt)₄, Si(CH₃)₄, (CH₃)₃SiH or a mixture thereof. In this context, Me refers to methyl, Et refers to ethyl, Bu refers to butyl, t refers to tert, and Pr refers to propyl, for the respective groups.

The silicon precursor can be provided to the reaction chamber using a carrier gas. Exemplary suitable carrier gases include one or more of Ar, He, N₂. A flowrate of the carrier gas used to provide the silicon precursor to the reaction chamber can be between about 100 and about 5000 sccm or between about 2000 and about 4000 sccm.

During step 106, the nitrogen-containing reactant is provided within the reaction chamber. As noted above, step 106 can overlap with step 104.

In accordance with various examples, the nitrogen-containing reactant does not include oxygen. In accordance with particular examples, the nitrogen-containing reactant includes nitrogen and hydrogen. Exemplary nitrogen-containing reactants suitable for step 106 include one or more of nitrogen (N₂), ammonia (NH₃), hydrazine (N₂H₄), triazane (N₃H₅), an (e.g., C1-C4)alkyl substituted hydrazine, triazine, or a C1-C4 amine. In accordance with more particular examples, the nitrogen-containing reactant comprises one or more of N₂, NH₃, NH₄, N₂H₂, N₂H₄, or a mixture thereof. A flowrate of the nitrogen-containing reactant to the reaction chamber can be between about 75 and about 2500 sccm.

During step 108, a plasma is formed within the reaction chamber while providing one or more of the silicon precursor and the nitrogen-containing reactant by providing a plasma power to an electrode within the reaction chamber. In accordance with examples of the disclosure, a frequency of the plasma power is equal to or greater than 60 MHz or between about 60 MHz and about 100 MHz. An intensity of power used to form the plasma can be between about 200 and about 1200 W.

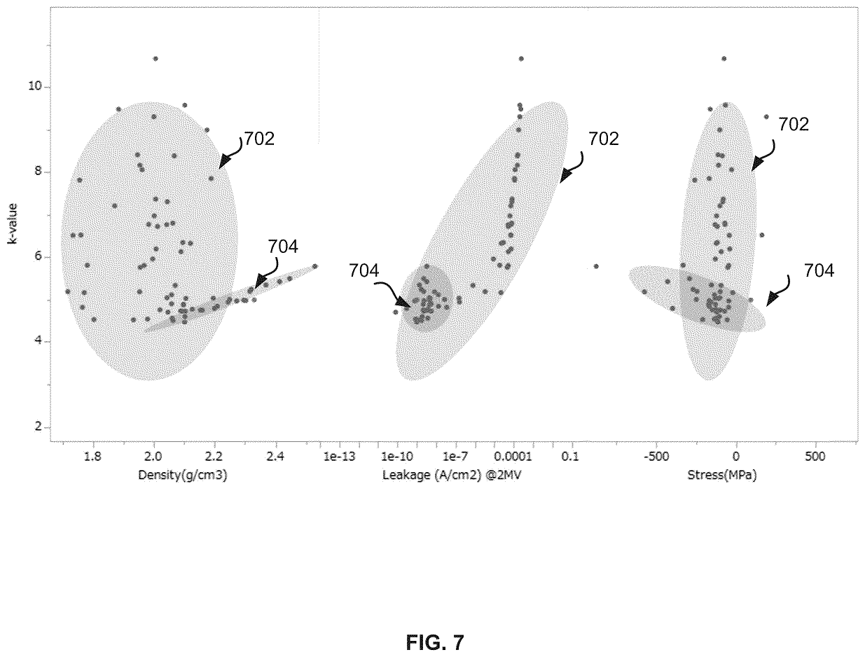

Use of plasma power with a frequency equal to or greater than 60 MHz expands an available range of process parameters that can be used to adjust a quality (e.g., density, dielectric constant, or the like) of a deposited silicon carbon nitride layer. For example, use of 60 MHz or higher frequency power can produce silicon carbon nitride layers with relatively low dielectric constant, while maintaining desired film density. Table 1 below illustrates various properties of a silicon carbon nitride layer formed using plasma power having 60 MHz or higher frequency power versus lower frequency power—e.g., less than 20 MHz. FIG. 7 illustrates dielectric constants versus film density, leakage, and stress for silicon carbon nitride layers deposited using 60 MHz (data 702) and 13.56 MHz (data 704) using the same or similar conditions. As illustrated, use of 60 MHz or higher frequency power versus lower frequency (e.g., 20 MHz or 15 MHz or less) power reduces a dielectric constant in the layers, and can reduce stress, while maintaining desired density.

TABLE 1

| | | | 60 MHz |
|---|---|---|---|
| | Target | 13.56 MHz | Example |
| Density(g/cm³) | ≥2.3 (g/cm³) | 2.32 | 2.33 |
| K value | <3.4-3.8 | 5.2 | 5.0 |
| | (single or multi- | | |
| | layer) | | |
| Leakage @2MV/cm | <10E−9 | 1.7E−9 | 1.0E−9 |
| @20 nm | | @100 nm | @100 nm |
| Vbd @1E−3 A/cm² | Matched or better | 6.5 | 7.5 |
| @20 nm | than current | @100 nm | @100 nm |
| Vbd @1E−6 A/cm² | Intel BKM at | No | 5.0 |
| @20 nm | Equivalent thickness | Measurement | @100 nm |
| Compressive Stress | −300 > × > −450 | −269 | 94 |
| (MPa) | | | |
| D/R nm/min | — | 48 | 48 |
| Reflective Index | | 1.892 | 1.805 |
| @633 nm | | | |
| Thickness non- | <4.0 | 3.2 | 7.6 |
| uniformity (%) | | @EE3 mm | @EE3 mm |
| @EE2 mm | | | |

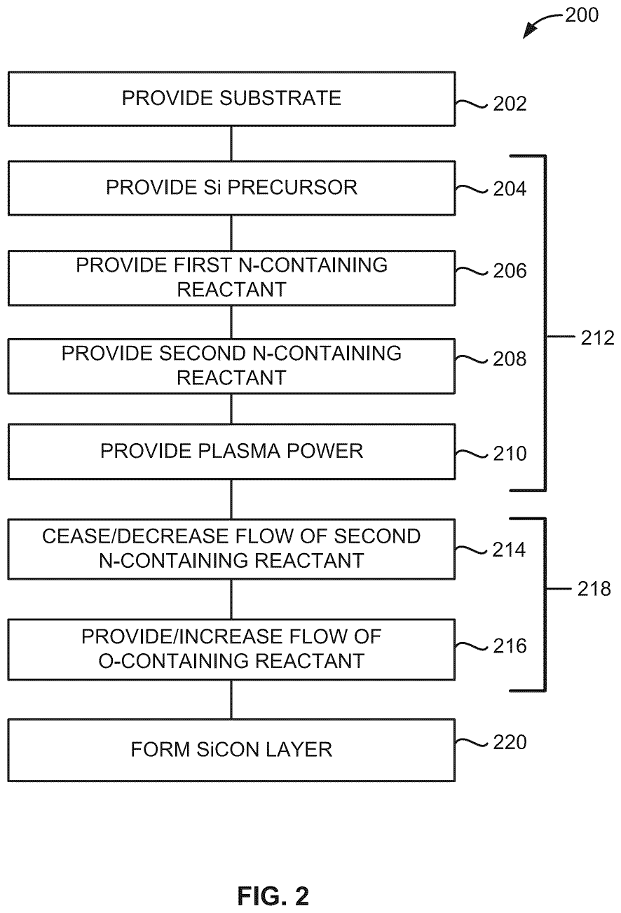

Although not separately illustrated, in accordance with various examples of the disclosure, method 100 can further include a step of forming a silicon carbon oxynitride layer on the silicon carbon nitride layer. The step of forming a silicon carbon oxynitride layer can be as described below in connection with FIG. 2.

FIG. 2 illustrates another method 200. Method 200 is a continuous method used to form a structure comprising a silicon carbon nitride layer and a silicon carbon oxynitride layer. Typically, such layers are formed using separate or non-continuous processes in which a first plasma is formed to form the first layer, and another plasma is formed to form the second layer. In contrast, method 100 employs a continuous plasma to form both the silicon carbon nitride layer and the silicon carbon oxynitride layer.

As illustrated, method 200 includes the steps of providing a substrate within a reaction chamber (202), providing a silicon precursor within the reaction chamber (204), providing a first nitrogen-containing reactant within the reaction chamber (206), providing a second nitrogen-containing reactant within the reaction chamber (208), forming a plasma by providing plasma power within the reaction chamber while providing one or more of the silicon precursor and the first nitrogen-containing reactant to form the layer of silicon carbon nitride (210), while maintaining the plasma, decreasing a flow of the second nitrogen-containing reactant (214) and providing or increasing a flow of an oxygen-containing reactant (216) during a transition period (218), and while continuing to maintain the plasma, forming the silicon carbon oxynitride layer (220).

Steps 202 and 204 can be the same or similar to steps 102 and 104 described above. For example, the reaction chamber temperatures and/or pressures and the silicon precursors can be as noted above in connection with steps 102 and 104.

Step 206 and/or step 208 can be the same or similar to step 106 described above. For example, the first and/or second nitrogen-containing reactants can be or include any of the nitrogen-containing reactants described above. In some cases, the first and second nitrogen-containing reactants can be different. By way of particular examples, the first nitrogen-containing reactant can be or include one or more of NH₃ or N₂. Additionally or alternatively, the second nitrogen-containing reactant comprises one or more of N₂, NH₃, or a C1-C4 (e.g., alkyl) amine. The flowrates of the first and/or second nitrogen-containing reactants can be as described above in connection with step 106.

During step 210, a plasma is formed within the reaction chamber while providing one or more of the silicon precursor and the nitrogen-containing reactant by providing a plasma power to an electrode within the reaction chamber. In accordance with examples of the disclosure, a frequency of the plasma power is equal to or greater than 60 MHz or between about 60 MHz and about 100 MHz. An intensity of power used to form the plasma can be between about 200 and about 1200 W. In accordance with some examples of the disclosure, the step of forming the plasma includes providing a dual frequency plasma power, wherein at least one frequency of the dual frequency plasma power is equal to or greater than 60 MHz. The other frequency can be in a range of, for example, between about 60 MHz and about 100 MHz.

Steps 204-210 can overlap, such that the layer of silicon carbon nitride is formed, at least in part, using a PECVD process 212, which includes steps 204-210. After a specified duration or a desired thickness (e.g., about 1 to about 20 nm) of the silicon carbon nitride layer is formed, method 200 proceeds to a transition step 218 that, in the illustrated example, includes while maintaining the plasma, ceasing or decreasing a flow of the second nitrogen-containing reactant 214 and increasing flow of or providing an oxygen-containing reactant 216.

In accordance with examples of the disclosure, a flowrate of the second nitrogen-containing reactant can decrease by about 85 percent or more during transition period 218. In accordance with additional examples, the flowrate of the second nitrogen-containing reactant can decrease by 3000 sccm or more.

The oxygen-containing reactant provided during step 218 can be or include an oxygen-containing gas. In some cases, the oxygen-containing reactant comprises carbon. In some cases, the oxygen-containing reactant comprises a mixture comprising a hydrogen-containing gas. By way of particular examples, the oxygen-containing reactant or gas can be or include CO₂. Additionally or alternatively, the hydrogen-containing gas can be or include H₂, NH₄.

A duration of transition step 218 can be between about 2.0 and about 6.0 seconds. During this step, one or more of the flow of the second nitrogen-containing reactant is decreased and/or the flow of the oxygen-containing reactant is increased.

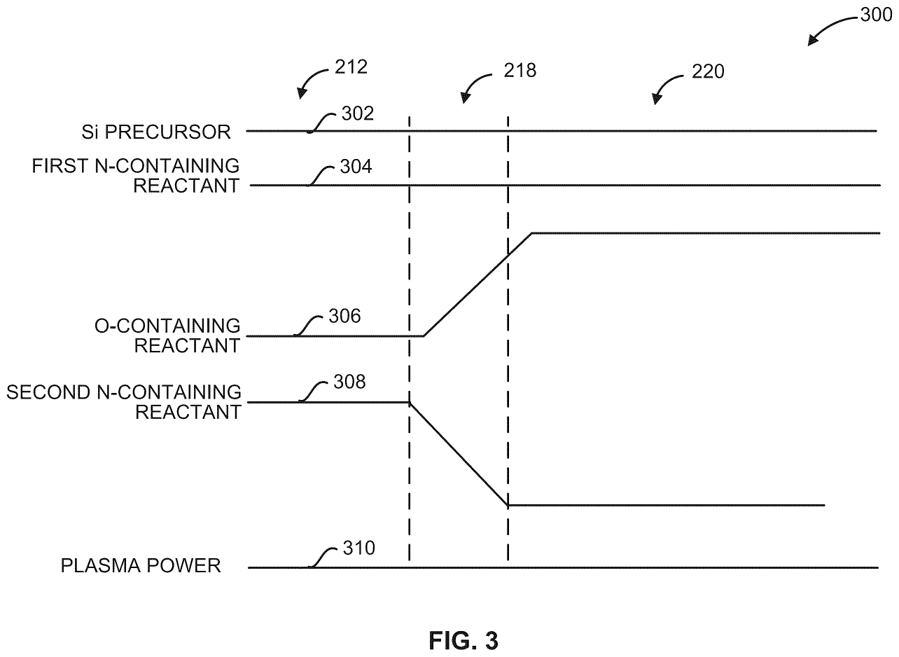

FIG. 3 illustrates a timing sequence 300 suitable for use with method 200. As illustrated, timing sequence 300 includes a silicon carbon nitride layer formation step 212, a transition step 218, and a silicon carbon oxynitride layer formation step 220. As further illustrated in FIG. 3, a providing the silicon precursor step 302, a providing the first nitrogen-containing reactant 304, and providing plasma power (e.g., high and low frequency plasma power) 310 are continuous (e.g., remain substantially constant or about the same) through timing sequence 300. As described above, a providing a second nitrogen-containing reactant step 308 can decrease during transition step 218 and can thereafter continue (e.g., remain substantially constant) during step 220. Providing the oxygen-containing reactant step 306 can increase during transition step 218 and can thereafter continue (e.g., remain substantially constant) during step 220.

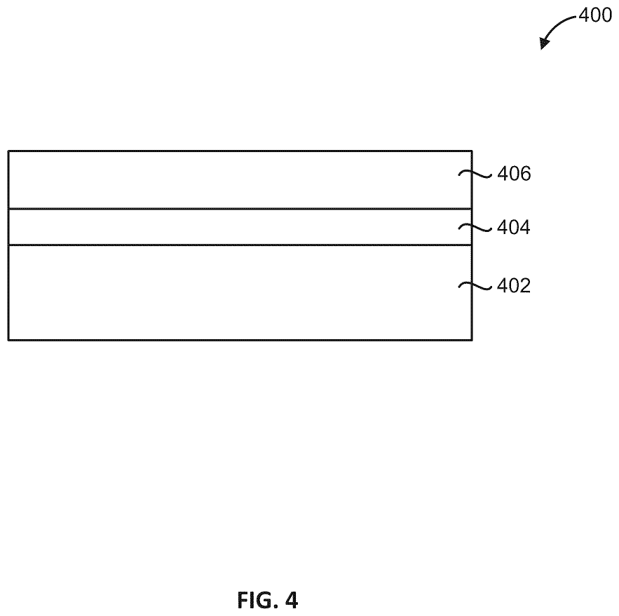

FIG. 4 illustrates a structure 400 formed using method 200. Structure 400 includes a substrate 402, a silicon carbon nitride layer 404 formed (e.g., directly) on substrate 402, and a silicon carbon oxynitride layer 406 formed (e.g., directly) on silicon carbon nitride layer 404.

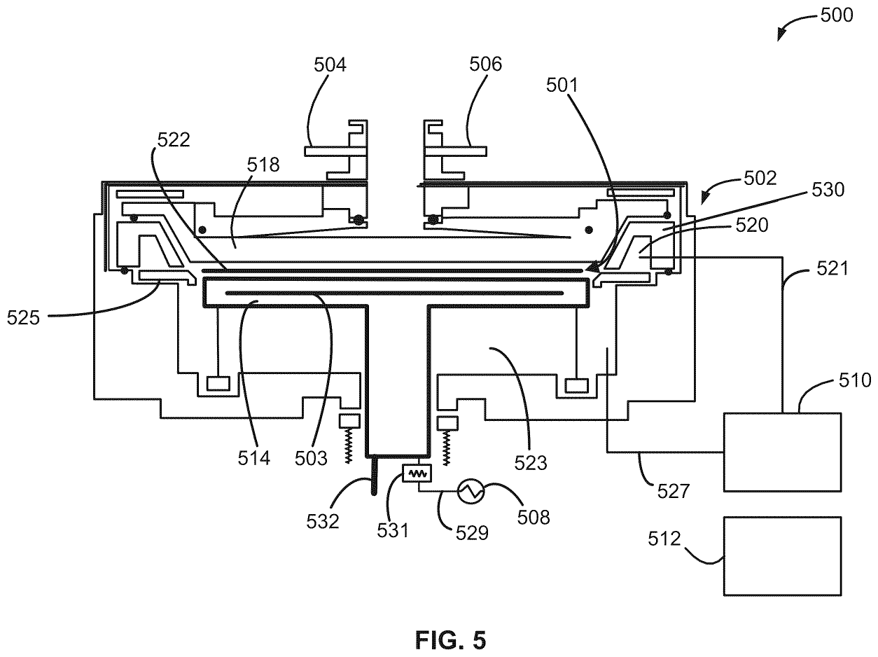

A reactor system 500 in accordance with exemplary embodiments of the disclosure is illustrated in FIG. 5. Reactor system 500 can be used to perform one or more steps or substeps as described herein and/or to form one or more structures or portions thereof as described herein.

Reactor system 500 includes a pair of electrically conductive flat-plate electrodes 514, 518 in parallel and facing each other in an interior 501 (reaction zone) of a reaction chamber 502. A plasma can be excited within reaction chamber 502 by applying, for example, plasma power from plasma power source(s) 508 to one electrode (e.g., electrode 514) and electrically grounding the other electrode (e.g., electrode 518). Power source(s) 508 can be coupled to electrode 514 via a transmission line 529 and an RF filter 531. A temperature regulator 503 can be provided in a lower stage 514 (the lower electrode), and a temperature of a substrate 522 placed thereon can be kept at a desired temperature, such as the temperatures noted above. Electrode 518 can serve as a gas distribution device, such as a shower plate or showerhead. Precursor gases, reactant gases, and a carrier or inert gas, if any, or the like can be introduced into reaction chamber 502 using one or more gas lines (e.g., reactant gas line 504 and precursor gas line 506, respectively, coupled to a reactant source and a precursor source). For example, an inert gas and a reactant (e.g., as described above) can be introduced into reaction chamber 502 using line 504 and/or a precursor, and a carrier gas (e.g., an inert gas as described above) can be introduced into the reaction chamber 502 using line 506. Although illustrated with two inlet gas lines 504, 506, reactor system 500 can include any suitable number of gas lines.

In reaction chamber 502, a circular duct 520 with an exhaust line 521 can be formed within a metallic duct plate 530, through which gas in the interior 501 of the reaction chamber 502 can be exhausted to an exhaust source 510. Additionally, a transfer chamber 523 can be provided with a seal gas line 532 to introduce seal gas into the interior 501 of reaction chamber 502 via the interior (transfer zone) of transfer chamber 523, wherein a separation plate 525 for separating the reaction zone 501 and the transfer chamber 523 can be provided (a gate valve through which a substrate is transferred into or from transfer chamber 523 is omitted from this figure). Transfer chamber 523 can also be provided with an exhaust line 527 coupled to exhaust source 510. In some embodiments, continuous flow of a carrier gas to reaction chamber 502 can be accomplished using a flow-pass system (FPS).

Reactor system 500 can include one or more controller(s) 512 programmed or otherwise configured to cause one or more method steps as described herein to be conducted. Controller(s) 512 are coupled with the various power sources, heating systems, pumps, robotics and gas flow controllers, or valves of the reactor, as will be appreciated by the skilled artisan. By way of example, controller 512 can be configured to control gas flow of a precursor, a reactant, and an inert gas into at least one of the one or more reaction chambers to form a layer on a surface of a substrate. Controller 512 can be further configured to provide power to form a plasma—e.g., within reaction chamber 502. Controller 512 can be similarly configured to perform additional or alternative steps as described herein. By way of examples, controller 512 can be configured to perform a continuous method for forming a structure comprising a silicon carbon nitride layer and a silicon carbon oxynitride layer as described above.

Controller 512 can include electronic circuitry and software to selectively operate valves, manifolds, heaters, pumps and other components included in system 500. Such circuitry and components operate to introduce precursors, reactants, and purge gases from the respective sources. Controller 512 can control timing of gas pulse sequences, temperature of the substrate and/or reaction chamber, pressure within the reaction chamber, and various other operations to provide proper operation of the system 500.

Controller 512 can include control software to electrically or pneumatically control valves to control flow of precursors, reactants, and/or purge gases into and out of the reaction chamber 502. Controller 512 can include modules, such as a software or hardware component, e.g., a FPGA or ASIC, which performs certain tasks. A module can advantageously be configured to reside on the addressable storage medium of the control system and be configured to execute one or more processes.

In some embodiments, a dual chamber reactor (two sections or compartments for processing substrates disposed close to each other) can be used, wherein a reactant gas and a noble gas can be supplied through a shared line, whereas a precursor gas is supplied through unshared lines.

During operation of system 500, substrates, such as semiconductor wafers, are transferred from, e.g., a substrate handling area 523 to the reaction zone 501. Once substrate(s) are transferred to reaction zone 501, one or more gases, such as precursors, reactants, carrier gases, and/or purge gases, are introduced into reaction chamber 502.

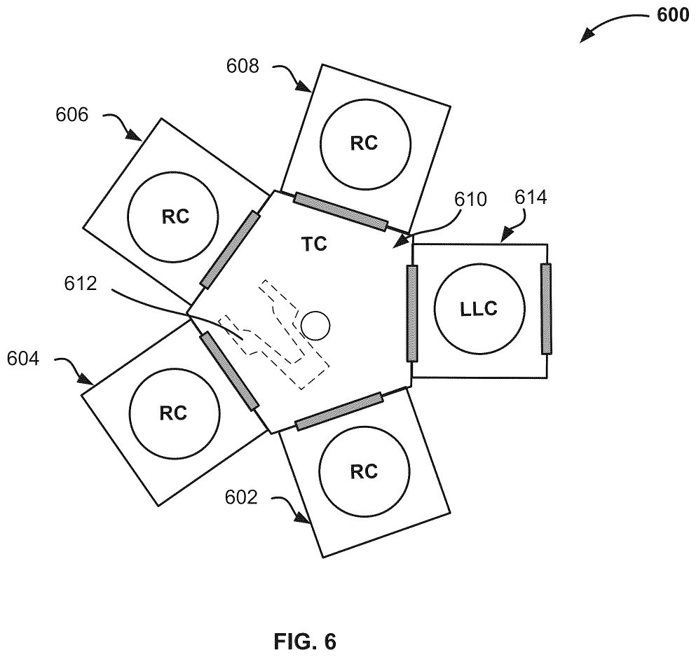

FIG. 6 illustrates a reactor system 600 that includes a plurality of reaction chambers 602-608, each of which can be an example of reaction chamber 502 in FIG. 5. Reaction chambers 602-608 can be disposed around and/or coupled to a transfer chamber 610 that includes a transfer tool 612 for transferring substrates between reaction chambers 602-608 and a load lock chamber 614, and between reaction chambers 602-608 (e.g., through transfer chamber 610). For example, a substrate 530 can be disposed in different chambers for different steps of a method described herein.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of forming a structure comprising a silicon carbon nitride layer, the method comprising:
providing a substrate within a reaction chamber;
providing a silicon precursor within the reaction chamber;
providing a nitrogen-containing reactant within the reaction chamber; and
forming a plasma within the reaction chamber while providing one or more of the silicon precursor and the nitrogen-containing reactant,
wherein forming the plasma comprises providing a plasma power to an electrode within the reaction chamber, and
wherein a frequency of the plasma power is equal to or greater than 60 MHz.

2. The method of claim 1, wherein the silicon precursor comprises one or more of an aminosilane or an alkylsilane.

3. The method of claim 2, wherein the silicon precursor comprises one or more of (SiH₃)₂NMe, (SiH₃)₂NEt, (SiH₃)₂N(iPr), (SiH₃)₂N(tBu), SiH₃NEt₂, SiH₃N(tBu)₂, SiH₂ (NEt₂)₂, SiH₂(NMe₂)₂, SiH₂(NHtBu)₂, SiH₂(NHSiMe₃)₂, SiH₃N(iPr)₂, SiH(N(Me)₂)₃, SiH₂[N(Et)(Me)]₂, Si₂(NHEt)₆, Si(NHEt)₄, Si(CH₃)₄, (CH₃)₃SiH or a mixture thereof.

4. The method of claim 1, wherein the nitrogen-containing reactant comprises one or more of nitrogen, ammonia (NH₃), hydrazine (N₂H₄), triazane (N₃H₅), an alkyl substituted hydrazine, triazine, or a C1-C4 amine.

5. The method of claim 1, wherein the nitrogen-containing reactant comprises one or more of N₂, NH₃, NH₄, N₂H₂, N₂H₄, or a mixture thereof.

6. The method of claim 1, wherein a density of the silicon carbon nitride layer is greater than 2.3 g/cm³.

7. The method of claim 6, wherein a dielectric constant of the silicon carbon nitride layer is less than 5.

8. The method of claim 1, further comprising a step of forming a silicon carbon oxynitride layer on the silicon carbon nitride layer.

9. A continuous method for forming a structure comprising a silicon carbon nitride layer and a silicon carbon oxynitride layer, the method comprising the steps of:
providing a substrate within a reaction chamber;
providing a silicon precursor within the reaction chamber;
providing a first nitrogen-containing reactant within the reaction chamber;
providing a second nitrogen-containing reactant within the reaction chamber;
forming a plasma by providing plasma power within the reaction chamber while providing one or more of the silicon precursor and the first nitrogen-containing reactant to form the layer of silicon carbon nitride;
while maintaining the plasma, decreasing a flow of the second nitrogen-containing reactant and providing an oxygen-containing reactant during a transition period; and
while continuing to maintain the plasma, forming the silicon carbon oxynitride layer.

10. The method of claim 9, wherein a frequency of the plasma power is equal to or greater than 60 MHz.

11. The method of claim 9, wherein the step of forming the plasma comprises providing a dual frequency plasma power, wherein at least one frequency of the dual frequency plasma power is equal to or greater than 60 MHz.

12. The method of claim 9, wherein the silicon precursor comprises one or more of aminosilane or alkylsilane.

13. The method of claim 9, wherein the silicon precursor comprises one or more of (SiH₃)₂NMe, (SiH₃)₂Net, (SiH₃)₂N(iPr), (SiH₃)₂N(tBu), SiH₃NEt₂, SiH₃N(tBu)₂, SiH₂(NEt₂)₂, SiH₂(NMe₂)₂, SiH₂(NHtBu)₂, SiH₂(NHSiMe₃)₂, SiH₃N(iPr)₂, SiH(N(Me)₂)₃, SiH₂[N(Et)(Me)]₂, Si₂(NHEt)₆, Si(NHEt)₄, Si(CH₃)₄, (CH₃)₃SiH or a mixture thereof.

14. The method of claim 9, wherein the first nitrogen-containing reactant comprises one or more of N₂, ammonia (NH₃), hydrazine (N₂H₄), triazane (N₃H₅), a C1-C4 alkyl substituted hydrazine, triazine, or a C1-C4 amine.

15. The method of claim 9, wherein the first nitrogen-containing reactant comprises one or more of NH₃ or N₂.

16. The method of claim 9, wherein the second nitrogen-containing reactant comprises one or more of N₂, NH₃, or a C1-C4 amine.

17. The method of claim 9, wherein a flowrate of the second nitrogen-containing reactant decreases by about 40 percent or more during the transition period.

18. The method of claim 9, wherein the oxygen-containing reactant comprises carbon.

19. The method of claim 9, wherein the oxygen-containing reactant comprises a mixture comprising a hydrogen-containing gas.

20. The method of claim 19, wherein the hydrogen-containing gas comprises one or more of H₂ or NH₄.
